(19) United States
(12) Patent Application Publication
(10) Pub. No.: US 2026/0140167 A1
(43) Pub. Date: May 21, 2026

(54) SEMICONDUCTOR TEST APPARATUS

(71) Applicants: Samsung Electronics Co., Ltd., Suwon-si (KR); IUCF-HYU(Industry-University Cooperation Foundation Hanyang University), Seoul (KR)

(72) Inventors: Hyunmi HONG, Suwon-si (KR); Dongeun SHIN, Suwon-si (KR); Seonmi LEE, Suwon-si (KR); Dahm YU, Suwon-si (KR); Jihyun CHOI, Suwon-si (KR); Hongyun SO, Seoul (KR); Junho KIM, Seoul (KR); Sangyeun PARK, Seoul (KR); Byungkwon CHUN, Seoul (KR)

(73) Assignees: Samsung Electronics Co., Ltd., Suwon-si (KR); IUCF-HYU(Industry-University Cooperation Foundation Hanyang University), Seoul (KR)

(21) Appl. No.: 19/259,078

(22) Filed: Jul. 3, 2025

(30) Foreign Application Priority Data
Nov. 21, 2024 (KR) 10-2024-0167649

(51) Int. Cl. G01R 31/28; G01R 1/04

(52) U.S. Cl. CPC G01R 31/2875; G01R 1/0458; G01R 31/2877

(57) ABSTRACT

A semiconductor test apparatus includes a chamber, at least one high-temperature chuck in the chamber, at least one low-temperature chuck opposite the at least one high-temperature chuck, at least one semiconductor test board between the at least one high-temperature chuck and the at least one low-temperature chuck, and a rack configured to move the at least one semiconductor test board within a space between the at least one high-temperature chuck and the at least one low-temperature chuck.

### CROSS-REFERENCE TO RELATED APPLICATION(S)

This U.S. non-provisional application claims the benefit of priority to Korean Patent Application No. 10-2024-0167649 filed on Nov. 21, 2024 in the Korean Intellectual Property Office, the disclosure of which is incorporated herein by reference in its entirety.

### BACKGROUND

Some example embodiments of the inventive concepts relate to a test chamber, specifically a semiconductor test apparatus capable of controlling a test board configured to control a temperature in the test chamber so that it is a uniform temperature, improve a temperature change rate at which an internal temperature of the chamber falls or rises to a high temperature and a low temperature, and/or improve a temperature conversion rate between the high and low temperatures, desired and/or necessary for tests, a system including the same, and/or a method of operating the same, etc.

In general, functional tests, including burn-in board tests in which adverse conditions, such as adverse temperature and/or adverse voltage, are applied, may be performed to detect initial defects in semiconductor devices, such as integrated circuit (IC) chips, etc.

A function test of a semiconductor device may be conducted by a semiconductor test apparatus. A burn-in board test, designed to detect initial semiconductor defects, may require an extended test duration, such that a device under test (DUT) mounted on a board may be maximized to improve productivity. To this end, a plurality of DUT boards may be stacked in multiple layers and tested simultaneously.

A semiconductor test apparatus may test a DUT under conditions more severe than those encountered in a general-use environment (for example, room temperature, etc.) to more rapidly detect errors occurring in a semiconductor device in the general-use environment and to predict potential defects in the semiconductor device that may arise after the DUT is shipped.

Current semiconductor test apparatuses may utilize thermal convection of air in a chamber, achieved via a heater or chiller, to control an internal temperature of the chamber.

Such semiconductor test apparatuses may operate at temperatures ranging from 45° C. to 125° C. In addition, when changing the internal temperature of the chamber to a high or low temperature and/or converting between the high and low temperatures, temperature control via thermal convection may result in temperature variations across different areas of the board and/or between interlayer boards.

In addition, temperature control via air convection may result in temperature non-uniformity throughout the chamber, including between multilayered boards and/or between positions in which DUTs are mounted on the boards in various layers. Such non-uniformity may require extended and/or prolonged testing durations to achieve uniform temperature distribution.

### SUMMARY

At least one example embodiment of the inventive concepts provides a semiconductor test apparatus for improving test efficiency by reducing a temperature change rate and/or a temperature conversion rate of a DUT (DUT) in a chamber.

At least one example embodiment of the inventive concepts provides a semiconductor test apparatus reducing and/or preventing temperature non-uniformity between different positions of a DUT mounted on a test board from occurring.

According to at least one example embodiment of the inventive concepts, there is provided a semiconductor test apparatus including a chamber, at least one high-temperature chuck in the chamber, at least one low-temperature chuck opposite the at least one high-temperature chuck, at least one semiconductor test board between the at least one high-temperature chuck and the at least one low-temperature chuck, and a rack configured to move the at least one semiconductor test board within a space between the at least one high-temperature chuck and the at least one low-temperature chuck.

According to at least one example embodiment of the inventive concepts, there is provided a semiconductor test apparatus for testing at least one device under test (DUT), the semiconductor apparatus including a chamber having an internal space, a chuck assembly including at least one first chuck and at least one second chuck alternately stacked in a vertical direction in the internal space, the chuck assembly configured to conduct heat to at least one DUT, at least one semiconductor test board between the at least one first chuck and the at least one second chuck, the at least one semiconductor test board configured to store the at least one DUT, and a movement device configured to move at least one of the chuck assembly and the at least one semiconductor test board, such that the at least one semiconductor test board is heated by at least one of the at least one first chuck and the at least one second chuck.

According to at least one example embodiment of the inventive concepts, there is provided a semiconductor test apparatus including a chamber having an internal space, at least one first chuck in the internal space, a contact housing on a lower surface of the at least one first chuck, the contact housing including a plurality of contact protrusions protruding downwardly, a semiconductor test board including a plurality of sockets, the plurality of sockets configured to respectively receive a plurality of devices under test (DUTs), the semiconductor test board configured to electrically connect to the plurality of DUTs through the plurality of sockets, and a rack configured to move the semiconductor test board such that the plurality of contact protrusions contact the plurality of DUTs.

According to at least one example embodiment of the inventive concepts, there is provided a system including a chamber configured to hold a plurality of chuck assemblies, each of the chuck assemblies including a first chuck and a second chuck, and a rack configured to hold a plurality of semiconductor test boards, each of the semiconductor test boards including a plurality of sockets configured to hold a plurality of devices under test (DUTs), the rack further configured to move such that the plurality of semiconductor test boards inserted into an open spaces in the plurality of chuck assemblies.

Some example embodiments provide that the rack is further configured to move such that the plurality of semiconductor test boards are moved closer to the first chucks included in the plurality of chuck assemblies.

Some example embodiments provide that the rack is further configured to move such that the plurality of semiconductor test boards are moved closer to the second chucks included in the plurality of chuck assemblies.

Some example embodiments provide that the first chuck includes a plurality of protrusions, and the first chuck is configured to transfer heat to the plurality of protrusions.

Some example embodiments provide that the plurality of protrusions are configured to heat the plurality of DUTs in response to the plurality of protrusions contacting the plurality of DUTs.

### BRIEF DESCRIPTION OF DRAWINGS

The above and other aspects, features, and advantages of one or more example embodiments of the inventive concepts will be more clearly understood from the following detailed description, taken in conjunction with the accompanying drawings, in which:

FIG. 1 is a schematic perspective view of a semiconductor test apparatus according to at least one example embodiment of the inventive concepts;

FIG. 2 is a schematic perspective view of a state in which a high-temperature chuck and a low-temperature chuck are alternating in the semiconductor test apparatus of FIG. 1 according to at least one example embodiment;

FIG. 3 is a schematic perspective view of a state in which a test board to be functionally tested in the semiconductor test apparatus of FIG. 1 is in a vertical rack according to at least one example embodiment;

FIG. 4 is a schematic perspective view of a test board inserted into a space between a high-temperature chuck and a low-temperature chuck according to at least one example embodiment;

FIG. 5 is a schematic perspective view of a test board according to at least one example embodiment of the inventive concepts;

FIG. 6 is a schematic diagram of a state in which a semiconductor test apparatus is driven according to at least one example embodiment of the inventive concepts;

FIG. 7 is a schematic diagram of a state in which a test board is adjacent to a low-temperature chuck in a semiconductor test apparatus according to at least one example embodiment of the inventive concepts;

FIG. 8 is a schematic diagram of a state in which a test board is adjacent to a high-temperature chuck in a semiconductor test apparatus according to at least one example embodiment of the inventive concepts;

FIG. 9 is a schematic diagram of a semiconductor test apparatus including a contact module according to at least one example embodiment of the inventive concepts;

FIG. 10 is a schematic perspective view of a contact module according to at least one example embodiment of the inventive concepts;

FIG. 11 is a schematic plan view of a contact module according to at least one embodiment of the inventive concepts;

FIG. 12 is a schematic cross-sectional view of an operation of a contact module according to at least one example embodiment of the inventive concepts;

FIG. 13 is a schematic perspective view of a contact module according to at least one example embodiment of the inventive concepts;

FIG. 14 is a schematic plan view of a contact module according to at least one example embodiment of the inventive concepts;

FIG. 15 is a schematic cross-sectional view of an operation of a contact module according to at least one example embodiment of the inventive concepts;

FIG. 16 is a schematic perspective view of a contact module according to at least one example embodiment of the inventive concepts;

FIG. 17 is a schematic plan view of a contact module according to at least one example embodiment of the inventive concepts; and

FIG. 18 is a schematic cross-sectional view of an operation of a contact module according to at least one example embodiment of the inventive concepts.

### DETAILED DESCRIPTION

Hereinafter, some example embodiments of the inventive concepts will be described with reference to the attached drawings.

Some example embodiments of the inventive concepts are described herein to provide a description of the inventive concepts to those of ordinary skill in the art. Accordingly, the shapes and sizes of the components in the drawings may be exaggerated for clarity of description, and components denoted by the same reference numerals in the drawings may be the same components. One or more example embodiments of the inventive concepts may be modified into many different forms and/or may be varied.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.”

As used herein, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

The terms used herein describe particular example embodiments only, and the inventive concepts are not limited thereby. As used herein, singular forms “a,” “an,” and “the” are intended to include the plural forms as well, unless the context clearly indicates otherwise.

### Semiconductor Test Apparatus

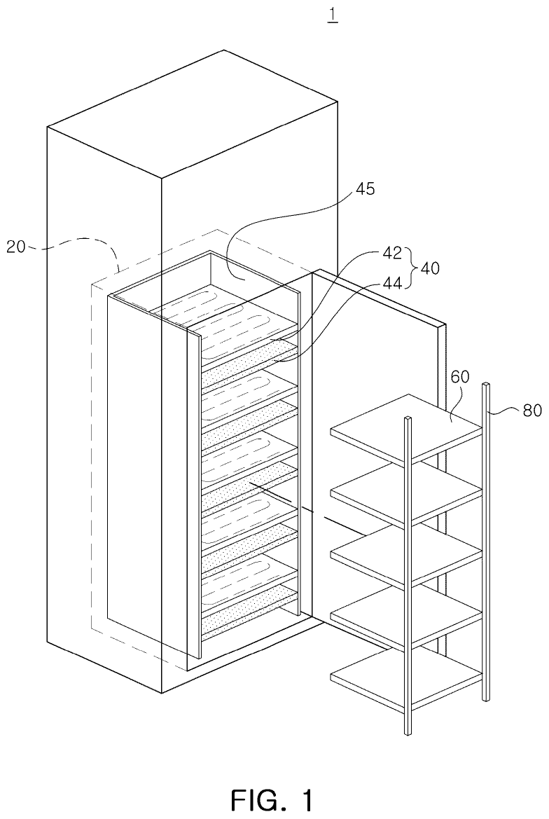

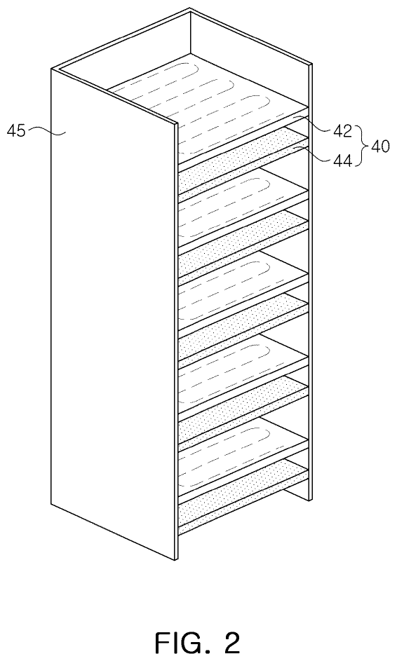

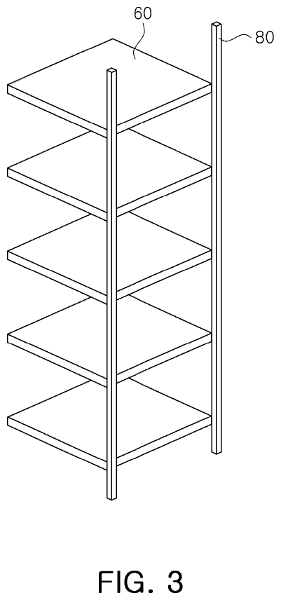

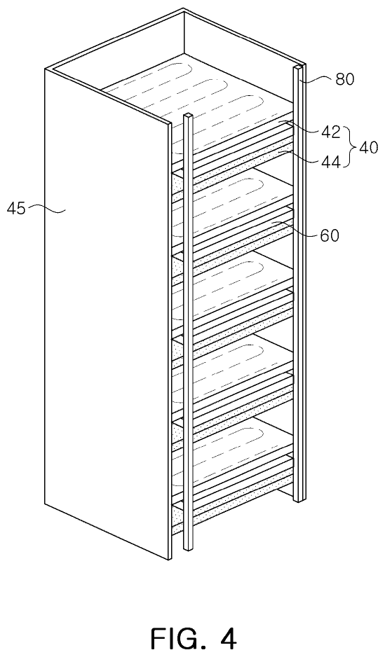

FIG. 1 is a schematic perspective view of a semiconductor test apparatus according to at least one example embodiment of the inventive concepts. FIG. 2 is a schematic perspective view of a state in which a high-temperature chuck and a low-temperature chuck are alternated on the semiconductor test apparatus of FIG. 1 according to at least one example embodiment. FIG. 3 is a schematic perspective view of a state in which a test board to be functionally tested in the semiconductor test apparatus of FIG. 1 is on a vertical rack according to at least one example embodiment. FIG. 4 is a schematic perspective view of a test board inserted into a space between a high-temperature chuck and a low-temperature chuck according to at least one example embodiment.

A semiconductor test apparatus 1 according to at least one example embodiment of the inventive concepts includes a chamber 1, at least one high-temperature chuck 42, at least one low-temperature chuck 44, at least one semiconductor test board 60, and/or at least one rack 80, etc., but the example embodiments are not limited thereto.

The semiconductor test apparatus 1 may be an apparatus capable of performing various semiconductor function tests, including a burn-in test, etc., which are used to identify initial defects in semiconductor devices before supplying the semiconductor integrated circuit (IC) devices, semiconductor packages, or the like, to consumers and/or before installing the above-described devices, packages, or the like, in systems.

Here, during the burn-in test, after a semiconductor chip separated from a wafer is packaged using an assembly process, a specific stress environment may be created to identify a defective and/or faulty device. The burn-in test may be an inspection for detecting the presence and/or absence of a final defect in a semiconductor package manufactured in the form of a package, but is not limited thereto. Through the burn-in test, the reliability of semiconductors may be improved and/or ensured, thereby allowing electronic devices, such as PCs, storage devices, etc., and/or IT products in which the semiconductors are installed, may be operated with reduced errors and/or without errors.

In at least one example embodiment of the inventive concepts, one or more devices, such as a semiconductor chip and/or a semiconductor package, etc., tested by the semiconductor test apparatus 1 are defined and described as a device under test (DUT).

The chamber 1 may have an internal space, and at least one high-temperature chuck 42 and/or at least one low-temperature chuck 44 may be located at intervals inside the chamber 1 so as to oppose each other.

The high-temperature chuck 42 and the low-temperature chuck 44 may be attached, connected, and/or fixed through at least one slot formed in a wall of the chamber 1 and/or a frame structure 45. In at least one example embodiment, the high-temperature chuck 42 and the low-temperature chuck 44 vertically oppose each other. However, the example embodiments are not limited thereto, and for example, when the high-temperature chuck 42 and the low-temperature chuck 44 are configured to perform heat transfer using a thermal conduction method, the high-temperature chuck 42 and the low-temperature chuck 44 may also horizontally oppose each other, etc.

The semiconductor test board 60 may include at least one DUT U, and may be located at intervals between the high-temperature chuck 42 and the low-temperature chuck 44, etc.

The high-temperature chuck 42 and/or the low-temperature chuck 44 may be thermal conductors, but the example embodiments are not limited thereto, and for example, other types of functional chucks may be used for other functional tests, such as voltage tests or the like. Accordingly, the high-temperature chuck 42 and the low-temperature chuck 44 may be defined as a first chuck or a second chuck, respectively.

Here, the first and second chucks may perform different functions, but may also perform the same function.

In addition, in order to test a relatively large number of devices simultaneously, a plurality of first chucks and second chucks may be configured. In the burn-in test, a plurality of pairs of first and second chucks, in which the high-temperature chuck 42 and the low-temperature chuck 44 oppose each other, may be configured. In this case, a single semiconductor test board 60 may be inserted into each of intervals, or in other words a semiconductor test board 60 may be inserted between each pair of high-temperature chucks 42 and low-temperature chucks 44, etc.

The burn-in board test may desire and/or require a relatively long testing time, and it may be therefore desired and/or necessary to increase and/or maximize the number of DUTs U mounted on the semiconductor test board 60 to increase and/or improve productivity. To this end, a plurality of semiconductor test boards 60 may be stacked in multiple layers and tested simultaneously. For example, 24 layers of semiconductor test boards 60 may be inserted into a pair of high-temperature chuck 42 and low-temperature chuck 44, opposing each other, to perform testing, but the example embodiments are not limited thereto.

The DUT U of the semiconductor test board 60 may come into contact with and/or may be adjacent to the high-temperature chuck 42 and the low-temperature chuck 44 in order to receive high-temperature heat and/or low-temperature heat, such that the temperature of the DUT U may be rapidly increased and/or decreased.

The semiconductor test apparatus 1 may include a movement module (e.g., a movement device, etc.) to adjust the position the DUT U of the semiconductor test board 60 to come into contact with and/or to be adjacent to the high-temperature chuck 42 and/or the low-temperature chuck 44, etc.

First, when all of the first chucks and second chucks in the chamber 20 are defined as a chuck assembly 40, the movement module may move at least one of the chuck assembly 40 and/or the semiconductor test board 60, etc., but is not limited thereto. Additionally, the movement module may move the chuck assembly 40 and/or may move the frame structure 45 to which the first chuck and the second chuck are attached, connected and/or fixed through the slot to be adjacent to the semiconductor test board 60, etc.

In addition, the movement module may move the semiconductor test board 60. In this case, the movement module may include a rack 80 to which the semiconductor test board 60 is removably attached, connected, and/or fixed, but the example embodiments are not limited thereto.

The rack 80 may be configured such that the semiconductor test board 60 are located in at intervals corresponding to the spaces between the pairs of first chuck 42 and the second chuck 44, that is, the high-temperature chuck 42 and the low-temperature chuck 44, etc.

When the DUT U and the high-temperature chuck 42 are adjacent to each other or come into contact with each other by raising and/or lowering the semiconductor test board 60, high-temperature thermal conduction may be performed. When the DUT U and the low-temperature chuck 44 are adjacent to each other or come into contact with each other by raising and/or lowering the semiconductor test board 60, low-temperature thermal conduction may be performed.

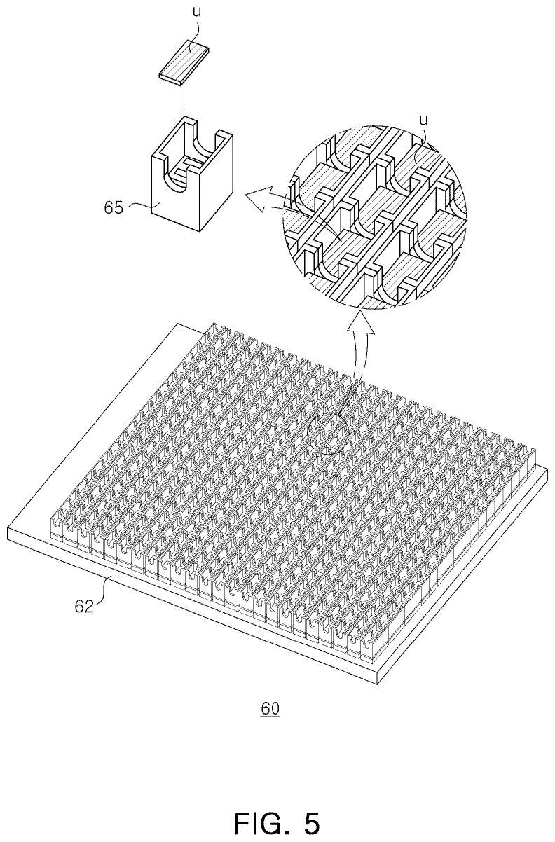

FIG. 5 is a schematic perspective view of a test board according to at least one example embodiment of the inventive concepts.

The semiconductor test board 60 of FIG. 5 may include a test board 62 and/or at least one socket 65, etc., but is not limited thereto.

A current and/or voltage (e.g., power, electricity, etc.) may flow through the DUT U via the test board 62. One or more DUTs U may be seated in one or more of the sockets 65, and the DUT U may be electrically connected to the test board 62.

The socket 65 may have a container shape having high sides to accommodate the DUT U, and may have a lower surface including an interconnection path which is electrically connected to the test board 62, but the example embodiments are not limited thereto.

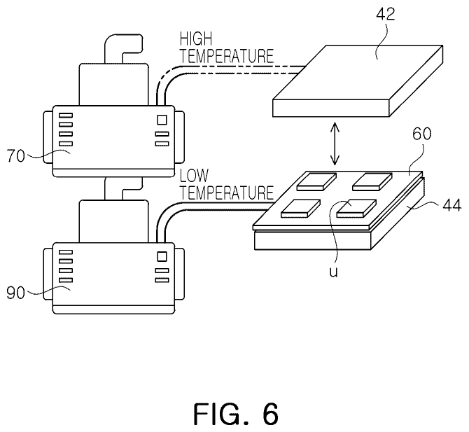

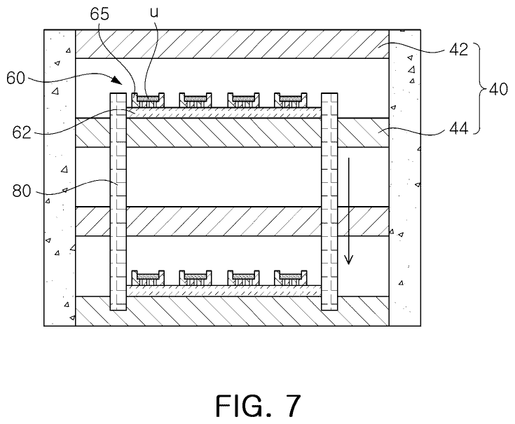

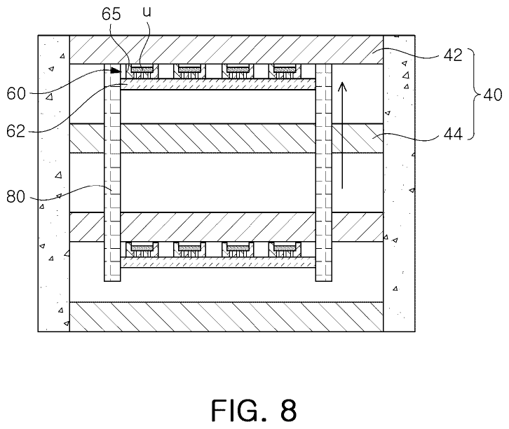

FIG. 6 is a schematic diagram of a state in which a semiconductor test apparatus is driven according to at least one example embodiment of the inventive concepts. FIG. 7 is a schematic diagram of a state in which a test board is adjacent to a low-temperature chuck in a semiconductor test apparatus according to at least one example embodiment of the inventive concepts. FIG. 8 is a schematic diagram of a state in which a test board is adjacent to a high-temperature chuck in a semiconductor test apparatus according to at least one example embodiment of the inventive concepts.

A state in which the semiconductor test apparatus 1 is driven according to at least one example embodiment of the inventive concepts will be described in detail with reference to FIGS. 6 and 7.

The socket 65 in which the DUT U is seated may be mounted on the test board 62. In addition, the semiconductor test board 60 may be attached and/or fixed to the rack 80, and the semiconductor test board 60 may be positioned between a pair of high-temperature chuck 42 and low-temperature chuck 44.

When the semiconductor test board 60 is positioned between the high-temperature chuck 42 and the low-temperature chuck 44, the DUT U may be exposed through a portion of the socket 65 that is open toward the high-temperature chuck 42, and the test board 62 may be positioned to be oriented toward the low-temperature chuck 44, but the example embodiments are not limited thereto.

When high-temperature conversion is performed, the rack 80 may be driven and/or moved to a position where the DUT U is adjacent to the high-temperature chuck 42. When low-temperature conversion is performed, the rack 80 may be driven and/or moved to a position where the DUT U is adjacent to the low-temperature chuck 42.

The driving (e.g., heating) of the high-temperature chuck 42, e.g., a thermal conductor, may be controlled by at least one of a high-temperature chiller, a heater, a thermoelectric device, and/or a heater, but is not limited thereto.

Referring now to FIG. 6, in at least one example embodiment, a high-temperature refrigerant may be allowed to flow to and/or through the high-temperature chuck 42 via a high-temperature chiller 70, such that the temperature of the DUT U may be increased, or in other words, the high-temperature chiller 70 may heat a refrigerant to a desired high temperature and provide the heated refrigerant to the high-temperature chuck 42, etc. A low-temperature refrigerant may be allowed to flow to and/or through the low-temperature chuck 44 via a low-temperature chiller 90, such that the temperature of the DUT U may be decreased, or in other words, a low-temperature chiller 90 may chill and/or cool a refrigerant and provide the chilled and/or cooled refrigerant to the low-temperature chuck 44, etc. However, the example embodiments are not limited thereto, and the high-temperature chuck 42 and/or the low-temperature chuck 44 may be respectively heated and chilled by alternate means, such as refrigerant-less means, etc.

As illustrated in FIG. 7, when the semiconductor test board 60 is lowered by driving and/or moving the rack 80, the DUT U and the low-temperature chuck 44 may be adjacent to each other or may come into contact with each other, such that low-temperature thermal conduction may be performed.

In this case, the low-temperature heat of the low-temperature chuck 44 may be conducted to the DUT U (e.g., heat from the relative high temperature of the DUT U may be transferred to the relatively lower temperature low-temperature chuck 44), such that the temperature of the DUT U may be decreased and/or rapidly decreased.

In addition, as illustrated in FIG. 8, when the semiconductor test board 60 is raised by driving and/or moving the rack 80, the DUT U and the high-temperature chuck 42 may be adjacent to each other or may come into contact with each other, such that high-temperature thermal conduction may be performed.

In this case, the high-temperature heat of the high-temperature chuck 42 may be conducted to the DUT U (e.g., heat from the relative high temperature of the high-temperature chuck 42 may be transferred to the relatively lower temperature DUT U), such that the temperature of the DUT U may be increased and/or rapidly increased.

According to the burn-in test using such a thermal conduction method, a test temperature conversion range and conversion time of the DUT U may be, for example, between approximately −25° C. and 90° C. within 5 minutes, respectively, and between approximately 45° C. and 125° C. within 8 minutes, respectively, but the example embodiments are not limited thereto.

In this case, heat may be transferred in a conduction manner, such that the entire area of the semiconductor test board 60 may have a temperature variation of ±3° C., and may be more uniformly maintained compared to a heat transfer method by convection.

The DUT U may not be thermally conducted to the high-temperature chuck 42 due to the container shape of the socket 65, decreasing and/or preventing direct contact with the high-temperature chuck 42. Accordingly, a contact module (e.g., a contact housing, etc.) capable of directly transferring the heat of the high-temperature chuck 42 to the DUT U may be between the high-temperature chuck 42 and the DUT U.

Hereinafter, the contact module (e.g., contact housing, etc.) will be described in detail.

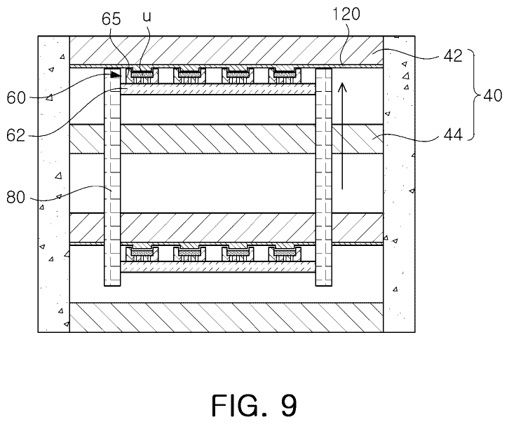

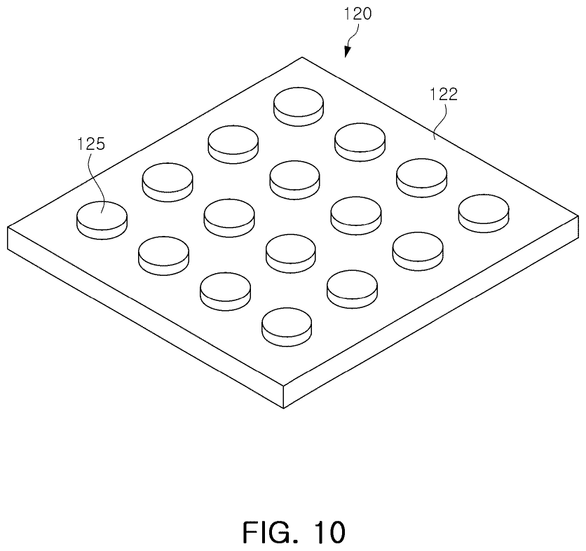

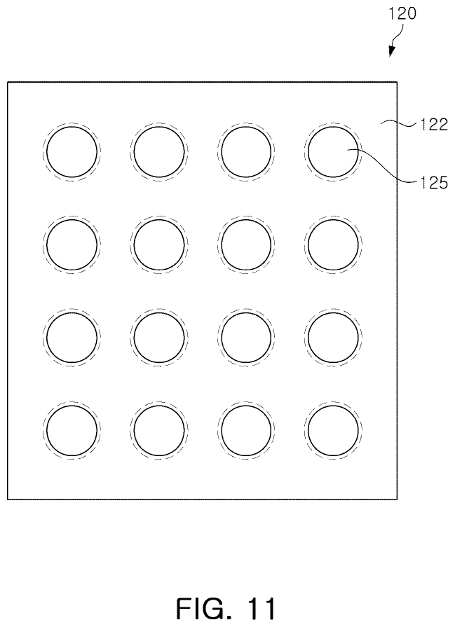

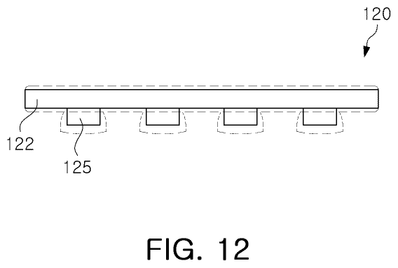

FIG. 9 is a schematic diagram of a semiconductor test apparatus including a contact module according to at least one example embodiment of the inventive concepts. FIG. 10 is a schematic perspective view of a contact module according to at least one example embodiment of the inventive concepts. FIG. 11 is a schematic plan view of a contact module according to at least one example embodiment of the inventive concepts. FIG. 12 is a schematic cross-sectional view of an operation of a contact module according to at least one example embodiment of the inventive concepts.

Referring to FIGS. 9 to 12, the semiconductor test apparatus 1 may further include a contact module 120 on a lower surface of the high-temperature chuck 42. Components other than the contact module 120 may be substantially the same as or similar to those described above, and thus repeated descriptions thereof will be omitted.

The low-temperature chuck 44 may not be used depending on the type of test being conducted, but the example embodiments are not limited thereto.

As illustrated in FIG. 9, the semiconductor test board 60 may be raised by driving and/or moving a rack 80, such that the DUT U and the high-temperature chuck 44 may be in direct contact with each other due to the contact module 120.

In this case, the high-temperature heat of the high-temperature chuck 42 may be conducted to the DUT U by the contact module 120, such that the temperature of the DUT U may be increased and/or more rapidly increased.

FIGS. 10 to 12 illustrate a shape of a contact module 120 according to at least one example embodiment. The contact module 120 of FIGS. 10 to 12 may include a heat transfer plate 122 and/or a plurality of contact protrusions 125, but is not limited thereto.

The heat transfer plate 122 may be a thermal conductor on a lower surface of the high-temperature chuck 42, and may directly transfer the high-temperature heat of the high-temperature chuck 42 to the DUT U in a conduction manner, but the example embodiments are not limited thereto.

The plurality of contact protrusions 125 may each extend toward at least one corresponding DUT U in a position corresponding to that of at least one socket 65 of the test board 60, or in other words, the plurality of contact protrusions 125 may extend downwards toward the test board 60, and the plurality of contact protrusions 125 may be aligned with the positions of the sockets 65 on the test board 60, etc.

When the heat of the high-temperature chuck 42 is transferred to the plurality of contact protrusions 125, the plurality of contact protrusions 125 may extend and expand due to the heat being transferred from the high-temperature chuck 42 and may come into contact with the at least one DUT U, such that heat transfer and/or high-rate heat transfer may be performed in a direct conduction manner.

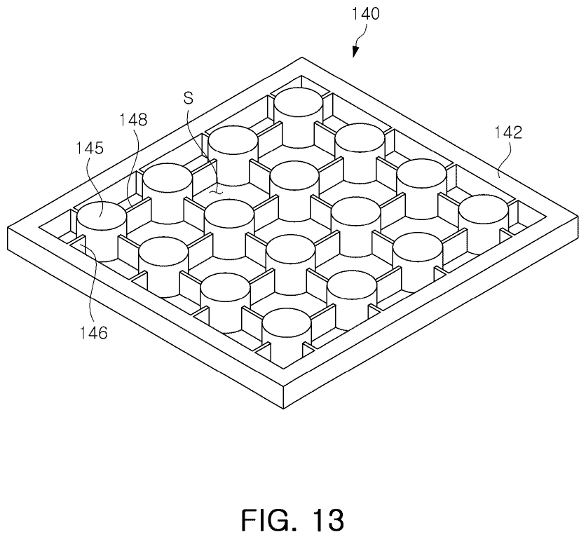

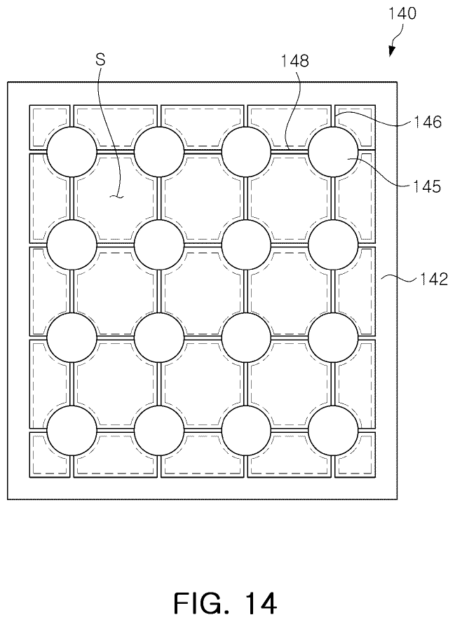

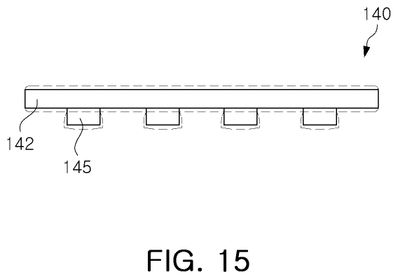

FIG. 13 is a schematic perspective view of a contact module according to at least one example embodiment of the inventive concepts. FIG. 14 is a schematic plan view of a contact module according to at least one example embodiment of the inventive concepts. FIG. 15 is a schematic cross-sectional view of an operation of a contact module according to at least one example embodiment of the inventive concepts.

FIGS. 13 to 15 illustrate a shape of a contact module 140 (e.g., a contact housing, etc.) of at least one example embodiment. The contact module 140 of FIGS. 13 to 15 (e.g., a contact device, etc.) may include an external frame 142, a plurality of contact protrusions 145, a first connection strip 146, and/or a second connection strip 148, etc., but is not limited thereto.

The external frame 142 may be a frame attached to and/or fixed below a high-temperature chuck 42.

The plurality of contact protrusions 145 may extend toward the semiconductor test board 60 which stores at least one DUT U stored in a plurality of sockets 65.

The plurality of first connection strips 146 and the plurality of second connection strips 148 may support the plurality of contact protrusions 145, such that the plurality of contact protrusions 145 may be positioned inside the external frame 142.

The plurality of first connection strip 146 may extend from the external frame 142 and may be connected to the plurality of protrusions 145, and/or the plurality of second connection strip 148 may be connected between two protrusions of the plurality of protrusions 145, but the example embodiments are not limited thereto.

The first connection strips 146 and the second connection strips 148 may have heights equal to or less than a height of the external frame 142, and thus may be connected to a lower portion and/or position on the side of the plurality of protrusions 145. In addition, the first connection strips 146 and/or the second connection strips 148 may be formed of a material capable of transferring heat to a thermal conductor, such as thin metal bands, etc., but are not limited thereto.

Here, the first connection strips 146 and the second connection strips 148 may be in a grid shape to form a space S between the first connection strip 146 and the second connection strip 148, but the example embodiments are not limited thereto.

The space S may provide elasticity when heat transfer contact occurs in a high-temperature environment, thereby further reducing the occurrence of cracks and/or reducing the occurrence of thermal deformation in the contact module 140, when compared to a case in which a plate is used as a single medium for heat for the one or more DUT U.

The first connection strips 146 and/or the second connection strips 148 may be restored and/or easily restored after thermal deformation occurs.

As illustrated in the dotted line of FIG. 15, the plurality of contact protrusions 145 may extend and/or expand due to heat transferred from the high-temperature chuck 42 to one or more of the DUTs U when the high-temperature chuck 42 comes into contact with one or more of the DUTs U, such that high-rate heat transfer may be performed in a direct conduction manner, but the example embodiments are not limited thereto.

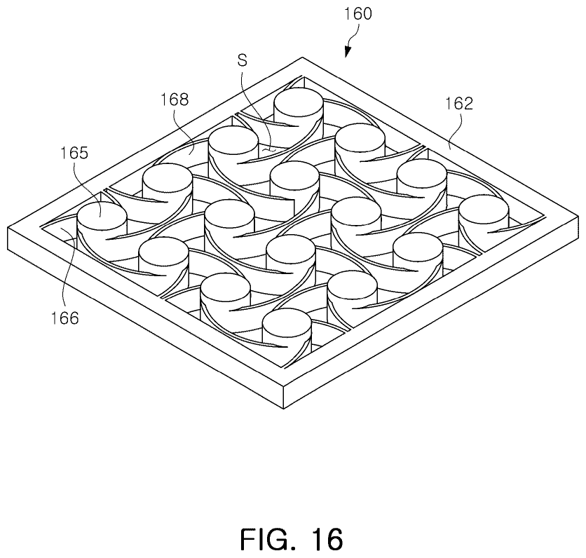

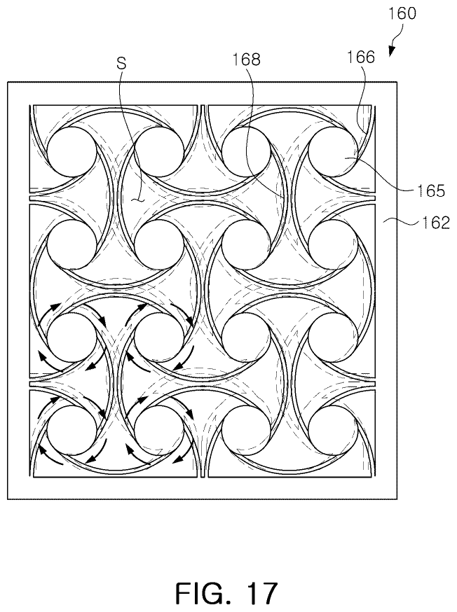

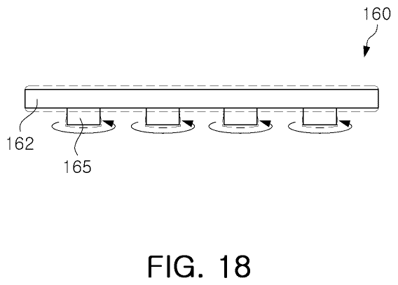

FIG. 16 is a schematic perspective view of a contact module according to at least one example embodiment of the inventive concepts. FIG. 17 is a schematic plan view of a contact module according to at least one example embodiment of the inventive concepts. FIG. 18 is a schematic cross-sectional view of an operation of a contact module according to at least one example embodiment of the inventive concepts.

FIGS. 16 to 18 illustrate a shape of a contact module 160 according to at least one example embodiment. The contact module 160 of FIGS. 16 to 18 may include an external frame 162, a plurality of contact protrusions 165, a first connection strip 166, and/or a second connection strip 168, etc., but is not limited thereto.

The external frame 162 may be a frame attached and/or fixed below a high-temperature chuck 42, but the example embodiments are not limited thereto.

The plurality of contact protrusions 165 may extend toward a DUT U in a position corresponding to a socket 65.

The first connection strip 166 and the second connection strip 168 may support the plurality of contact protrusions 165, such that the plurality of contact protrusions 165 may be positioned in the external frame 162.

The first connection strip 166 may extend from the external frame 162 and may be spirally connected to the plurality of protrusions 165, and the second connection strip 148 may be spirally connected between the plurality of protrusions 145.

The first connection strip 166 and the second connection strip 168 may have a height equal to or less than a height of the external frame 162, and thus may be connected to a lower portion and/or position on a side of the plurality of protrusions 165, but are not limited thereto. In addition, the first connection strip 166 and the second connection strip 168 include a material capable of transferring heat to a thermal conductor, such as thin metal bands, but the example embodiments are not limited thereto.

Here, the first connection strips 166 and/or the second connection strips 168 may be spirally connected to form a space S between the first connection strips 166 and the second connection strips 168, etc.

The space S may provide elasticity when heat transfer contact occurs in a high-temperature environment, thereby further reducing the occurrence of cracks and/or reducing the occurrence of thermal deformation in the contact module 160, in comparison to a case in which a single plate is used as a heat transfer medium.

Additionally, due to the shape of the first connection strip 166 and/or the second connection strip 168, the first connection strip 166 and/or the second connection strip 168 may be more easily restored after thermal deformation occurs.

As illustrated in the arrows and dotted lines of FIGS. 17 and 18, the plurality of contact protrusions 165 may extend and/or expand while rotating due to heat transferred from the high-temperature chuck 42, and may come into contact with the DUT U, such that improved heat transfer and/or high-rate heat transfer may be achieved in a direct conduction manner.

According to some example embodiments of the inventive concepts, in a semiconductor test apparatus, a semiconductor test board may move between a high-temperature chuck and a low-temperature chuck to reduce a temperature change rate of a DUT and/or a temperature conversion rate of the DUT in a chamber, thereby improving test efficiency of the DUT and/or reducing the amount of time to perform a test on the DUT.

In addition, a DUT may transfer heat using a conduction method in which a high-temperature chuck and/or a low-temperature chuck come into contact and/or substantially come into contact with each other, thereby performing high-rate temperature conversion.

In addition, a heat transfer contact module on a lower surface of a high-temperature chuck may allow heat to be transferred directly to a DUT mounted on a test board, thereby decreasing and/or preventing temperature non-uniformity from occurring based on a position of the DUT mounted on the test board.

While some example embodiments have been shown and described above, it will be apparent to those of ordinary skill in the art that modifications and variations could be made without departing from the scope of the inventive concepts as defined by the appended claims.

What is claimed is:

1. A semiconductor test apparatus comprising:
a chamber;
at least one high-temperature chuck in the chamber;
at least one low-temperature chuck opposite the at least one high-temperature chuck;
at least one semiconductor test board between the at least one high-temperature chuck and the at least one low-temperature chuck; and
a rack configured to move the at least one semiconductor test board within a space between the at least one high-temperature chuck and the at least one low-temperature chuck.

2. The semiconductor test apparatus of claim 1, wherein
the at least one high-temperature chuck is a plurality of high-temperature chucks;
the at least one low-temperature chuck is a plurality of low-temperature chucks;
the plurality of high-temperature chucks and the plurality of low-temperature chucks are alternately stacked in a vertical direction;
the at least one semiconductor test board is a plurality of semiconductor test boards; and
a single semiconductor test board of the plurality of semiconductor test boards is between a pair including one high-temperature chuck of the plurality of high-temperature chucks and one low-temperature chuck of the plurality of low-temperature chucks.

3. The semiconductor test apparatus of claim 1, further comprising:
at least one heating device configured to heat a thermal conductor included in the at least one high-temperature chuck; and
the at least one heating device is at least one of a high-temperature chiller, a heater, a thermoelectric device, or any combinations thereof.

4. The semiconductor test apparatus of claim 1, further comprising:
at least one chiller configured to chill a thermal conductor included in the at least one low-temperature chuck.

5. The semiconductor test apparatus of claim 1, wherein the at least one semiconductor test board includes:
a test board; and
a plurality of sockets electrically connected to the test board, the plurality of sockets configured to receive a plurality of devices under test (DUTs).

6. The semiconductor test apparatus of claim 5, wherein
the rack is further configured to be raised or lowered, the raising of the rack causing the plurality of DUTs to receive high-temperature heat from the at least one high-temperature chuck, and the lowering of the rack causing the plurality of DUTs to receive low-temperature heat from the at least one low-temperature chuck.

7. The semiconductor test apparatus of claim 5, further comprising:
a contact housing on a lower surface of the at least one high-temperature chuck, the contact housing including,
a heat transfer plate on the lower surface of the at least one high-temperature chuck, the heat transfer plate configured to transfer heat from the at least one high-temperature chuck heat to the plurality of DUTs, and
a plurality of contact protrusions extending toward the test board, the plurality of contact protrusions aligned with the plurality of sockets, and
wherein the plurality of contact protrusions extend or expand due to the heat transferred from the heat transfer plate to the plurality of DUTs.

8. The semiconductor test apparatus of claim 5, further comprising:
a contact housing on a lower surface of the high-temperature chuck, the contact housing including,
an external frame;
a plurality of contact protrusions extending toward the test board, the plurality of contact protrusions aligned with the plurality of sockets;
a plurality of first connection strips extending from the external frame, the plurality of first connection strips connected to the plurality of contact protrusions; and
a plurality of second connection strips, each of the plurality of second connection strips connected between at least two contact protrusions of the plurality of contact protrusions,
the plurality of first connection strips and the plurality of second connection strips have heights less than or equal to a height of the external frame,
the plurality of first connection strips, the plurality of second connection strips, and the plurality of contact protrusions are connected to form a plurality of grid shapes with interior open spaces, and
the plurality of contact protrusions extend or expand due to the heat transferred from the at least one high-temperature chuck.

9. The semiconductor test apparatus of claim 5, further comprising:
a contact housing on a lower surface of the at least one high-temperature chuck, the contact housing including,
an external frame;
a plurality of contact protrusions extending toward the test board, the plurality of contact protrusions aligned with the plurality of sockets;
a plurality of first connection strips extending from the external frame, the plurality of first connection strips spirally connected to the plurality of contact protrusions; and
a plurality of second connection strips spirally connected between the plurality of contact protrusions,
the plurality of first connection strips and the plurality of second connection strips have a height less than or equal to a height of the external frame,
the plurality of first connection strips, the plurality of second connection strips, and the plurality of contact protrusions are connected to each other to form open spaces, and
the plurality of contact protrusions extend or expand while rotating due to the heat transferred from the at least one high-temperature chuck.

10. A semiconductor test apparatus for testing at least one device under test (DUT), the semiconductor apparatus comprising:
a chamber having an internal space;
a chuck assembly including at least one first chuck and at least one second chuck alternately stacked in a vertical direction in the internal space, the chuck assembly configured to conduct heat to at least one DUT;
at least one semiconductor test board between the at least one first chuck and the at least one second chuck, the at least one semiconductor test board configured to store the at least one DUT; and
a movement device configured to move at least one of the chuck assembly and the at least one semiconductor test board, such that the at least one semiconductor test board is heated by at least one of the at least one first chuck and the at least one second chuck.

11. The semiconductor test apparatus of claim 10, wherein
the movement device includes a rack;
the rack is configured to,
receive the semiconductor test board, and
move the semiconductor test board between the at least one first chuck and the at least one second chuck;
the at least one first chuck is configured to apply high-temperature thermal conduction to the at least one DUT in response to the at least one first chuck being adjacent to the at least one DUT or in response to the at least one first chuck being in contact with the at least one DUT; and
the at least one second chuck is configured to apply low-temperature thermal conduction to the at least one DUT in response to the at least one second chuck being adjacent to the at least one DUT or in response to the at least one second chuck being in contact with the at least one DUT.

12. The semiconductor test apparatus of claim 11, further comprising:
a heating device is configured to control a temperature of a first thermal conductor included in the at least one first chuck, the heating device being at least one of a high-temperature chiller or a heater; and
a low-temperature chiller configured to control a temperature of a second thermal conductor included in the at least one second chuck.

13. The semiconductor test apparatus of claim 10, wherein the semiconductor test board includes:
a test board; and
a plurality of sockets electrically connected to the test board, the plurality of sockets configured to receive a plurality of DUTs, the plurality of DUTs including the at least one DUT.

14. The semiconductor test apparatus of claim 13, further comprising:
a contact housing on a lower surface of the at least one first chuck, the contact housing including,
a heat transfer plate on the lower surface of the at least one first chuck, the heat transfer plate configured to transfer heat from the at least one first chuck to a plurality of contact protrusions; and
the plurality of contact protrusions extending toward the test board, the plurality of contact protrusions aligned with the plurality of sockets, and
the plurality of contact protrusions extend or expand due to the heat transferred from the heat transfer plate.

15. The semiconductor test apparatus of claim 13, further comprising:
a contact housing on a lower surface of the first chuck, the contact housing including,
an external frame;
a plurality of contact protrusions extending toward the test board, the plurality of contact protrusions aligned with the plurality of sockets;
a plurality of first connection strips extending from the external frame, the plurality of first connection strips spirally connected to the plurality of contact protrusions; and
a plurality of second connection strips spirally connected between the plurality of contact protrusions,
the plurality of first connection strips and the plurality of second connection strips have a height less than or equal to a height of the external frame,
the plurality of first connection strips, the plurality of second connection strips, and the plurality of contact protrusions are connected to form grid shapes with interior open spaces, and
the plurality of contact protrusions extend or expand due to heat transferred from the at least one first chuck.

16. The semiconductor test apparatus of claim 13, further comprising:
a contact housing on a lower surface of the first chuck, the contact housing including,
an external frame;
a plurality of contact protrusions extending toward the test board, the plurality of contact protrusions aligned with the plurality of sockets;
a plurality of first connection strips extending from the external frame, the plurality of first connection strips spirally connected to the plurality of contact protrusions; and
a plurality of second connection strips spirally connected between the plurality of contact protrusions,
the plurality of first connection strips and the plurality of second connection strips have a height less than or equal to a height of the external frame,
the plurality of first connection strips, the plurality of second connection strips, and the plurality of contact protrusions are spirally connected to each other and form open spaces, and
the plurality of contact protrusions extend or expand while rotating due to heat transferred from the at least one first chuck.

17. A semiconductor test apparatus comprising:
a chamber having an internal space;
at least one first chuck in the internal space;
a contact housing on a lower surface of the at least one first chuck, the contact housing including a plurality of contact protrusions protruding downwardly;
a semiconductor test board including a plurality of sockets, the plurality of sockets configured to respectively receive a plurality of devices under test (DUTs), the semiconductor test board configured to electrically connect to the plurality of DUTs through the plurality of sockets; and
a rack configured to move the semiconductor test board such that the plurality of contact protrusions contact the plurality of DUTs.

18. The semiconductor test apparatus of claim 17, wherein
the contact housing includes a heat transfer plate, the heat transfer plate configured to transfer heat from the first chuck;
the plurality of contact protrusions extend toward the semiconductor test board, the plurality of contact protrusions aligned with the plurality of sockets; and
the plurality of contact protrusions extend or expand due to the heat transferred from the heat transfer plate.

19. The semiconductor test apparatus of claim 18, wherein the contact housing includes:
an external frame; and
a plurality of first connection strips extending from the external frame, the plurality of first connection strips connected to the plurality of contact protrusions; and
a plurality of second connection strips connected between the plurality of contact protrusions,
the plurality of first connection strips and the plurality of second connection strips have a height less than or equal to a height of the external frame,
the plurality of first connection strips, the plurality of second connection strips, and the plurality of contact protrusions are connected to form a plurality of grid shapes with interior open spaces, and
the plurality of contact protrusions extend or expand due to the heat transferred from the heat transfer plate.

20. The semiconductor test apparatus of claim 18, wherein the contact housing includes:
an external frame; and
a plurality of first connection strips extending from the external frame, the first plurality of connection strips spirally connected to the plurality of contact protrusions; and
a plurality of second connection strips spirally connected between the plurality of contact protrusions,
the plurality of first connection strips and the plurality of second connection strips have a height less than or equal to a height of the external frame,
the plurality of first connection strips, the plurality of second connection strips, and the plurality of contact protrusions are spirally connected to each other, and
the plurality of contact protrusions extend or expand while rotating due to the heat transferred from the heat transfer plate.
